(19) United States
(12) Patent Application Publication
(10) Pub. No.: US 2010/0218808 A1
(43) Pub. Date: Sep. 2, 2010

(54) CONCENTRATED PHOTOVOLTAIC SYSTEMS AND METHODS WITH HIGH COOLING RATES

(76) Inventor: Cristian Penciu, Dallas, TX (US)

Correspondence Address: Clements Bernard PLLC, 1901 Roxborough Road, Suite 250, Charlotte, NC, 28211, US

(21) Appl. No.: 12/780,528

(22) Filed: May 14, 2010

Related U.S. Application Data
(63) Continuation-in-part of application No. 12/212,249, filed on Sep. 17, 2008.
(60) Provisional application No. 60/993,946, filed on Sep. 17, 2007.
(60) Provisional application No. 61/011,298, filed on Jan. 16, 2008.
(60) Provisional application No. 61/063,508, filed on Feb. 4, 2008.
(60) Provisional application No. 61/066,371, filed on Feb. 20, 2008.

(51) Int. Cl. H01L 31/052

(52) U.S. Cl. 136/246

(57) ABSTRACT

The present disclosure relates to a concentrated photovoltaic (CPV) module, system, and method utilizing a CPV module to provide uniform, concentrated solar energy distribution over one or more photovoltaic (PV) cells, to improve cooling of the PV cells to allow for high solar concentration, and to offer an energy efficient system that can be cost effectively implemented. In an exemplary embodiment, the present invention includes solar collectors that concentrate solar energy and mechanisms for transporting and transferring the concentrated solar energy directly with the CPV module. Further, the CPV module includes a novel cooling mechanism utilizing a fluid to cool an interior of the module and the PV cells.

### CROSS-REFERENCE TO RELATED APPLICATION(S)

The present non-provisional patent application is a continuation-in-part of co-pending U.S. patent application Ser. No. 12/212,249, filed Sep. 17, 2008, and entitled “SYSTEMS AND METHODS FOR COLLECTING SOLAR ENERGY FOR CONVERSION TO ELECTRICAL ENERGY,” and co-pending U.S. patent application Ser. No. 12/212,408, filed Sep. 17, 2008, and entitled “APPARATUS FOR COLLECTING SOLAR ENERGY FOR CONVERSION TO ELECTRICAL ENERGY,” each of which claims priority to U.S. Provisional Patent Application Ser. No. 60/993,946, filed Sep. 17, 2007, entitled “METHOD AND APPARATUS FOR CONVERTING SOLAR ENERGY INTO ELECTRICAL ENERGY,” all of which are incorporated in full by reference herein.

### FIELD OF THE INVENTION

The present invention relates generally to a concentrated photovoltaic (CPV) systems and methods. More particularly, the present invention relates to a CPV module, system, and method utilizing a CPV module to provide uniform, concentrated solar energy distribution over one or more photovoltaic (PV) cells, to improve cooling of the PV cells to allow for high solar concentration, and to offer an energy efficient system that can be cost effectively implemented.

### BACKGROUND OF THE INVENTION

Concentrated photovoltaic (CPV) systems and methods provide concentrated solar radiation onto photovoltaic surfaces for electrical power production. Photovoltaic surfaces include a semiconductor material that converts solar radiation into direct current electricity. Exemplary materials may include monocrystalline silicon, polycrystalline silicon, microcrystalline silicon, cadmium telluride, copper indium selenide/sulfide, and the like. Of note, concentrated solar radiation on the semiconductor material provides improved efficiency in generating electricity. Photovoltaic (PV) cells require a uniform distribution of solar energy. Conventional solutions to provide a uniform distribution of concentrated solar radiation include an integrating sphere and utilizing PV cells at different wavelengths. These conventional solutions include various deficiencies related to providing uniform solar radiation over multiple PV cells, cooling of the PV cells to allow for extremely high solar radiation concentration, and overall cost effectiveness.

### BRIEF SUMMARY OF THE INVENTION

In an exemplary embodiment, a concentrated photovoltaic module includes a base including a cavity disposed therein; a top portion disposed to the base; an optical window in the top portion; one or more photovoltaic cells disposed to the top portion; and two or more openings in the base configured to provide a cooling fluid within the cavity. The cavity is dimensioned and shaped based upon the number of the one or more photovoltaic cells. The cavity is configured to provide a Lambertian distribution of concentrated solar radiation from the optical window to each of the one or more photovoltaic cells. The cavity may be coated with a high, diffuse reflectance material, and the high, diffuse reflectance material includes any of polytetrafluoroethylene, pressed magnesium oxide powder, and pressed barium sulfate powder. Alternatively, the base includes a high, diffuse reflectance material, wherein the cavity is formed in the base, and the high, diffuse reflectance material includes any of polytetrafluoroethylene, pressed magnesium oxide powder, and pressed barium sulfate powder. The optical window is configured to receive concentrated solar radiation from a solar collector, and wherein the concentrated solar radiation includes concentration of at least hundreds of Suns. The cooling fluid is substantially optically transparent and non-electrically conductive. The cooling fluid includes any of Germanium and Carbon tetrachloride.

In another exemplary embodiment, a concentrated photovoltaic system includes a concentrated photovoltaic module including a base including a cavity disposed therein; a top portion disposed to the base; an optical window in the top portion; one or more photovoltaic cells disposed to the top portion; and two or more openings in the base configured to provide a cooling fluid within the cavity; and a solar collector connected to the optical window. The cavity is dimensioned and shaped based upon the number of the one or more photovoltaic cells, and wherein the cavity is configured to provide a Lambertian distribution of concentrated solar radiation from the optical window to each of the one or more photovoltaic cells. Optionally, the cavity is coated with a high, diffuse reflectance material, and wherein the high, diffuse reflectance material includes any of polytetrafluoroethylene, pressed magnesium oxide powder, and pressed barium sulfate powder. Alternatively, the base includes a high, diffuse reflectance material, and wherein the cavity is formed in the base, and wherein the high, diffuse reflectance material includes any of polytetrafluoroethylene, pressed magnesium oxide powder, and pressed barium sulfate powder. The cooling fluid is substantially optically transparent and non-electrically conductive, and wherein the cooling fluid includes any of Germanium and Carbon tetrachloride. Optionally, the solar collector includes a primary reflector; a secondary reflector configured to receive solar energy reflected from the primary reflector and concentrate the solar energy; and an opening in the primary reflector, wherein the concentrated solar energy is provided by the secondary reflector to the opening; wherein the primary reflector and the secondary reflector each include inflatable components, and wherein the concentrated photovoltaic module is disposed to the opening in the primary reflector. Alternatively, the solar collector includes a primary reflector; a transparent and flexible material disposed to the primary reflector, wherein the transparent and flexible material is substantially optically transparent in the visible and infrared region; and wherein the primary reflector and the transparent and flexible material each includes inflatable components, and wherein the concentrated photovoltaic module is disposed to the transparent and flexible material.

In yet another exemplary embodiment, a concentrated photovoltaic method includes receiving concentrated solar radiation at an opening; deflecting the concentrated solar radiation off a cavity to one or more photovoltaic cells, wherein the concentrated solar radiation is deflected in a uniform distribution to each of the one or more photovoltaic cells; generating electricity at each of the one or more photovoltaic cells based upon the concentrated solar radiation; and cooling each of the one or more photovoltaic cells utilizing a cooling fluid in contact with at least one of the one or more photovoltaic cells. The cooling fluid is substantially optically transparent and non-electrically conductive. The cooling fluid includes any of Germanium and Carbon tetrachloride.

### BRIEF DESCRIPTION OF THE DRAWINGS

The present invention is illustrated and described herein with reference to the various drawings, in which like reference numbers denote like system components and/or method steps, respectively, and in which:

FIG. 1 is system schematic including a dual-surface reflector for collecting and concentrating solar energy according to an exemplary embodiment of the present invention;

FIG. 2 are multiple low-profile solar collectors for providing a flatter and compact low-profile arrangement according to an exemplary embodiment of the present invention;

FIG. 3 is a mechanism for combining solar radiation from multiple low-profile solar collectors through light guides according to an exemplary embodiment of the present invention;

FIG. 4 is a diagram of various designs for a focusing/collimating element according to an exemplary embodiment of the present invention;

FIG. 5 is a diagram of a modular solar collector according to an exemplary embodiment of the present invention;

FIG. 6 is a diagram of a concentrated photovoltaic (CPV) module according to an exemplary embodiment of the present invention;

FIG. 7 is a diagram of a dual-surface reflector for collecting and concentrating solar energy with the CPV module of FIG. 6 according to an exemplary embodiment of the present invention; and

FIG. 8 is a diagram of a single reflector for collecting and concentrating solar energy with the CPV module of FIG. 6 according to an exemplary embodiment of the present invention.

### DETAILED DESCRIPTION OF THE INVENTION

In various exemplary embodiments, the present invention relates to a CPV module, system, and method utilizing a CPV module to provide uniform, concentrated solar energy distribution over one or more photovoltaic (PV) cells, to improve cooling of the PV cells to allow for high solar concentration, and to offer an energy efficient system that can be cost effectively implemented. In an exemplary embodiment, the present invention includes solar collectors that concentrate solar energy and mechanisms for transporting and transferring the concentrated solar energy directly with the CPV module. Further, the CPV module includes a novel cooling mechanism utilizing a fluid to cool an interior of the module and the PV cells.

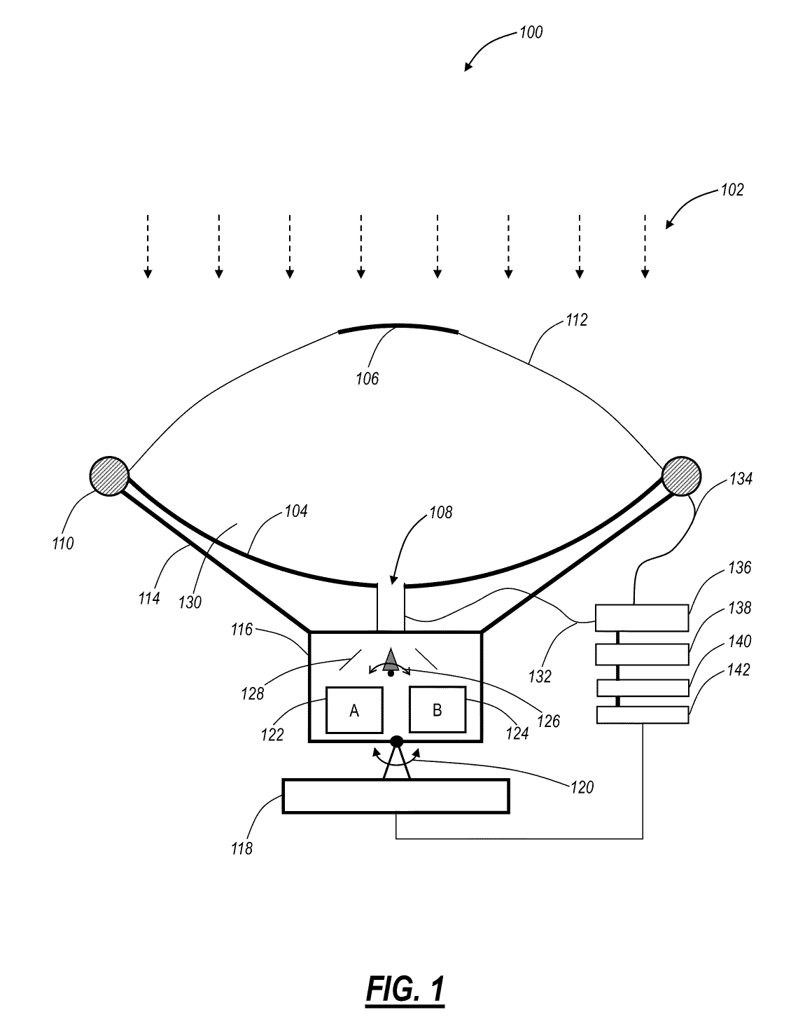

Referring to FIG. 1, a dual-surface reflector 100 is illustrated for collecting and concentrating solar energy 102 according to an exemplary embodiment of the present invention. The dual-surfaces on the dual-surface reflector 100 include a primary reflector 104 and a secondary reflector 106. The reflectors 104, 106 can be in a parabolic shape, a spherical shape, and the like. Also, the secondary reflector 106 can be concave or convex depending on the positioning of the secondary reflector 106 relative to the primary reflector 104. The primary reflector 104 is pointed towards the solar energy 102, and the secondary reflector 106 is located above the primary reflector 104. The primary reflector 104 is configured to reflect the solar energy 102 to the secondary reflector 106 which in turn concentrates the solar energy 102 through an opening 108 at a center of the primary reflector 104.

An outer perimeter support ring 110 is disposed around the edges of the primary reflector 104 to maintain the shape of the primary reflector 104 and to anchor in place the primary reflector 104. A transparent and flexible material 112 connects to the primary reflector 104 and to the support ring 110 to hold the secondary reflector 106 in place. The transparent and flexible material 112 is configured to allow the solar energy 102 to pass through, and can be constructed from a material that is optically transparent in the infrared region, such as a material in the Teflon® family of products, for example, fluorinated ethylene propylene (FEP) or the like. The transparent and flexible material 112 provides a closed design of the dual-surface reflector 100. Advantageously, the transparent and flexible material 112 can seal the dual-surface reflector 100 from the elements, i.e. wind, airborne particles, dirt, bird droppings, etc. This prevents deterioration of the reflectors 104, 106 and reduces maintenance with respect to cleaning the reflectors 104, 106.

A support member 114 can be disposed to the outer perimeter support ring 110 and a base 116. The base 116 can connect to a tracking mechanism 118 through a rotatable member 120. The tracking mechanism 118 is configured to continuously point the reflectors 104, 106 towards the sun by initiating a rotation of the rotatable member 120 to rotate the base 116, the support member 114 and the support ring 110. For example, the tracking mechanism 118 can include a microcontroller or the like can rotate according to location (e.g., an integrated Global Positioning Satellite (GPS) receiver, preprogrammed location, or the like), date, and time or the like. Additionally, the tracking mechanism 118 can include feedback from sensors that detect the position of the sun.

The base 116 can include one or more motors and electric generators 122, 124. The opening 108 is connected to the base 116 to provide concentrated solar energy from the reflectors 104, 106 to the one or more motors and electric generators 122, 124. For a single motor and electric generator 122, the motor and electric generator 122 is positioned to allow the concentrated solar energy to enter working fluid (e.g., a liquid, a gas, or a phase change substance) without heating an outside surface of the single motor and electric generator 122. The one or more motors and electric generators 122, 124 can include piezoelectric generators, closed-cycle thermodynamic engines, or variations of these.

FIG. 1 illustrates an exemplary embodiment with two of the motors and electric generators 122, 124. This exemplary embodiment includes an optical switch 126 and reflecting surfaces 128 to direct the concentrated solar energy into each of the motors and electric generators 122, 124. Those of ordinary skill in the art will recognize that the base 116 can include more than two of the motors and electric generators 122, 124 with a corresponding optical switch 126 and reflecting surfaces 128 to concentrate solar energy into each of the more than two of the motors and electric generators 122, 124. The optical switch 126 is configured to provide concentrated solar energy for predetermined intervals into each of the motors and electric generators 122, 124.

Advantageously, the optical switch 126 enables the dual-surface reflector 100 to input energy into each of the motors and electric generators 122, 124 in a pulsating manner only when needed and for a duration of time that is completely controllable. This enables the dual-surface reflector 100 to avoid wasting collected solar energy, i.e. the optical switch 126 enables the collected energy to be used in each of the motors and electric generators 122, 124 as needed. For example, the optical switch 126 can be configured to direct collected solar energy into a heating chamber of each of the motors and electric generators 122, 124 only during a heating cycle. The motors and electric generators 122, 124 each have offset heating cycles to allow all collected solar energy to be used, i.e. the optical switch 126 cycles between each of the motors and electric generators 122, 124 for their individual heating cycles.

In an exemplary embodiment, the dual-surface reflector 100 can include inflatable components, such as an inflatable portion 130 between the primary reflector 104 and the secondary reflector 106 and in the outer perimeter support ring 110. Air lines 132, 134 can be connected to the inflatable portion 130 and the outer perimeter support ring 110, respectively, to allow inflation through a valve 136, a pressure monitor 138, and an air pump 140. Additionally, a microcontroller 142 can be operably connected to the air pump 140, the pressure monitor 138, the valve 136, the tracking mechanism 118, etc. The microcontroller 142 can provide various control and monitoring functions of the dual-surface reflector 100.

Collectively, the components 136, 138, 140, 142 can be located within the base 116, attached to the base 116, in the tracking mechanism 118, external to the base 116 and the tracking mechanism 118, etc. The valve 136 can include multiple valves, such as, for example, an OFF valve, an ON/OFF line 132/134 valve, an OFF/ON ON/OFF line 132/134 valve, and so on for additional lines as needed, or the valve 136 can include multiple individual ON/OFF valves controlled by the microcontroller 142.

The inflatable components can be deflated and stored, such as in a compartment of the base 114. For example, the inflatable components could be stored in inclement weather, high winds, and the like to protect the inflatable components from damage. The microcontroller 142 can be connected to sensors which provide various feedback regarding current conditions, such as wind speed and the like. The microcontroller 142 can be configured to automatically deflate the inflatable components responsive to high winds, for example.

The support member 114 and the outer perimeter support ring 110, collectively, are configured to maintain the desired shape of the primary reflector 104, the secondary reflector 106, and the transparent and flexible material 112. The pressure monitor 138 is configured to provide feedback to the microcontroller 142 about the air pressure in the inflatable portion 130 and the outer perimeter support ring 110. The dual-surface reflector 100 can also include controllable relief pressure valves (not shown) to enable the release of air to deflate the dual-surface reflector 100. The transparent and flexible material 112 can form a closed space 130 which is inflated through the air line 132 to provide a shape of the secondary reflector 106, i.e. air is included in the interior of the dual-surface reflector 100 formed by the transparent and flexible material 112, the secondary reflector 106 and the primary reflector 104.

Advantageously, the inflatable components provide low cost and low weight. For example, the inflatable components can reduce the load requirements to support the dual-surface reflector 100, such as on a roof, for example. Also, the inflatable components can be transported more efficiently (due to the low cost and ability to deflate) and stored when not in use (in inclement weather, for example).

In another exemplary embodiment, the primary reflector 104, the support member 114, the outer perimeter support ring 110, the transparent and flexible material 112, etc. could be constructed through rigid materials which maintain shape. In this configuration, the components 136, 138, 140 are not required. The microcontroller 142 could be used in this configuration for control of the tracking mechanism 118 and general operations of the dual-surface reflector 100.

In both exemplary embodiments of the dual-surface reflector 100, the microcontroller 142 can include an external interface, such as through a network connection or direct connection, to enable user control of the dual-surface reflector 100. For example, the microcontroller 142 can include a user interface (UI) to enable custom settings.

The primary reflector 104 can be made from a flexible material such as a polymer (FEP) that is metalized with a thin, highly reflective metal layer that can be followed by additional coatings that protect and create high reflectance in the infrared region. Some of the metals that can be used for depositing a thin reflector layer on the polymer substrate material of the inflatable collector can include gold, aluminum, silver, or dielectric materials. Preferably, the surface of the primary reflector 104 is metalized and coated such that it is protected from contamination, scratching, weather, or other potentially damaging elements.

The secondary reflector 106 surface can be made in the same manner as the primary reflector 104 with the reflecting metal layer being deposited onto the inside surface of the secondary reflector 106. For improved performance, the secondary reflector 106 can be made out of a rigid material with a high precision reflective surface shape. In this case the, the secondary reflector can be directly attached to the transparent and flexible material 112 or be sealed to it (impermeable to air) around the perimeter of the secondary reflector 106. Both the primary reflector 104 and the secondary reflector 106 can utilize techniques to increase surface reflectivity (such as multi-layers) to almost 100%.

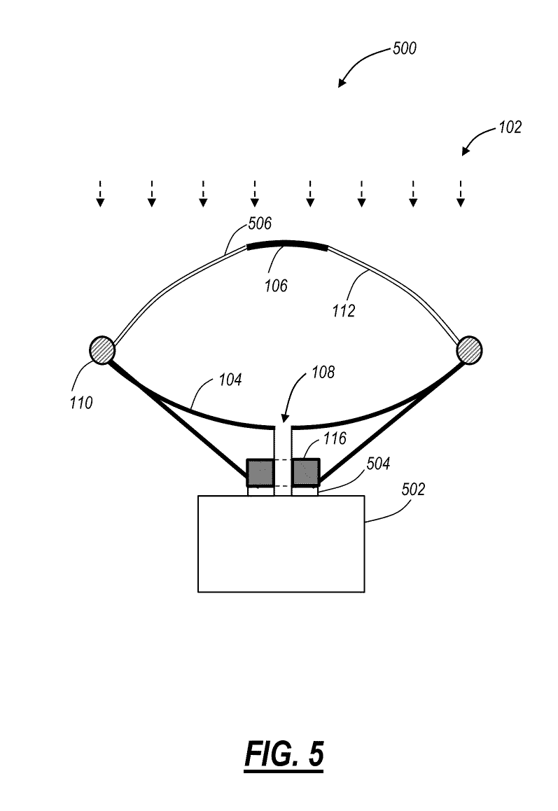

The dual-surface reflector 100 operates by receiving the solar energy 102 through solar radiation through the transparent and flexible material 112, the solar radiation reflects from the primary reflector 104 onto the secondary reflector 106 which collimates or slightly focuses the solar radiation towards the opening 108. One or more engines (described in FIG. 5) can be located at the opening 108 to receive the concentrated solar radiation (i.e., using the optical switch 126 and the reflectors 128 to enable multiple engines). The collimated or focused solar radiation from the secondary reflector 106 enters through optically transparent window on the engines towards a hot end (solar energy absorber) of a thermodynamic engine.

Advantageously, the dual-surface reflector 100 focuses the solar energy 102 and directs it into each of the motors and electric generators 122, 124 for their individual heating cycles in a manner that avoids heating engine components other than the solar energy absorber element in the heating chamber of the motors and electric generators 122, 124. Specifically, the opening 108 extends to the optical switch 126 which directs the concentrated solar energy directly into each of the motors and electric generators 122, 124 through a transparent window of the heating chamber. The materials forming the opening 108 and the transparent window include materials with absorption substantially close to zero for infrared radiation.

The dual-surface reflector 100 includes a large volume, and is preferably suitable for open spaces. For example, the dual-surface reflector 100 could be utilized in open-space solar farms for power plants, farms, etc. In an exemplary embodiment, the dual-surface reflector 100 could be four to six meters in diameter. Alternatively, the dual-surface reflector 100 could be a reduced size for individual home-use. Advantageously, the light weight of the inflatable components could enable use of the dual-surface reflector 100 on a roof. For example, a home-based dual-surface reflector 100 could be 0.1 to one meters in diameter. Also, the reduced cost could enable the use of the dual-surface reflector 100 as a backup generator, for example.

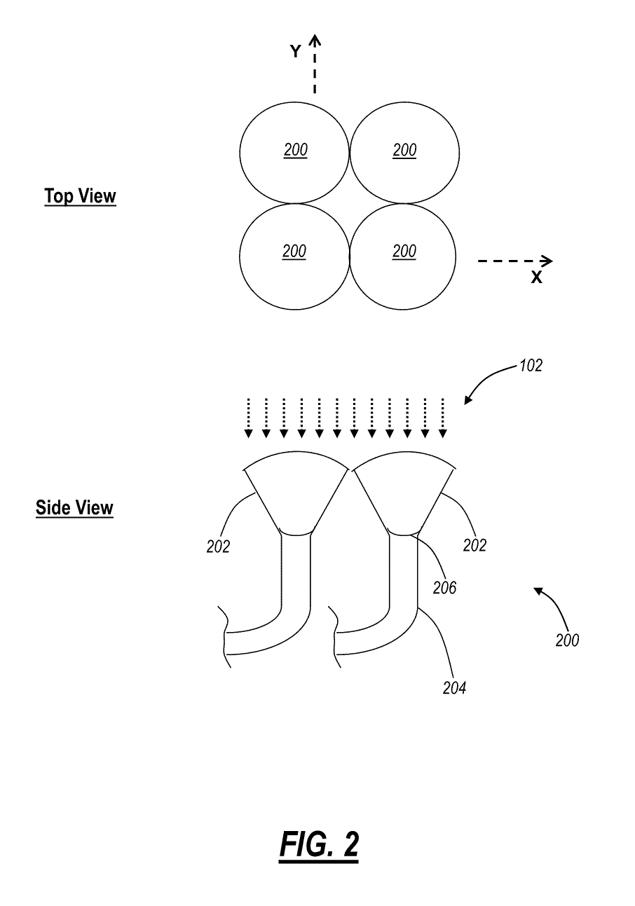

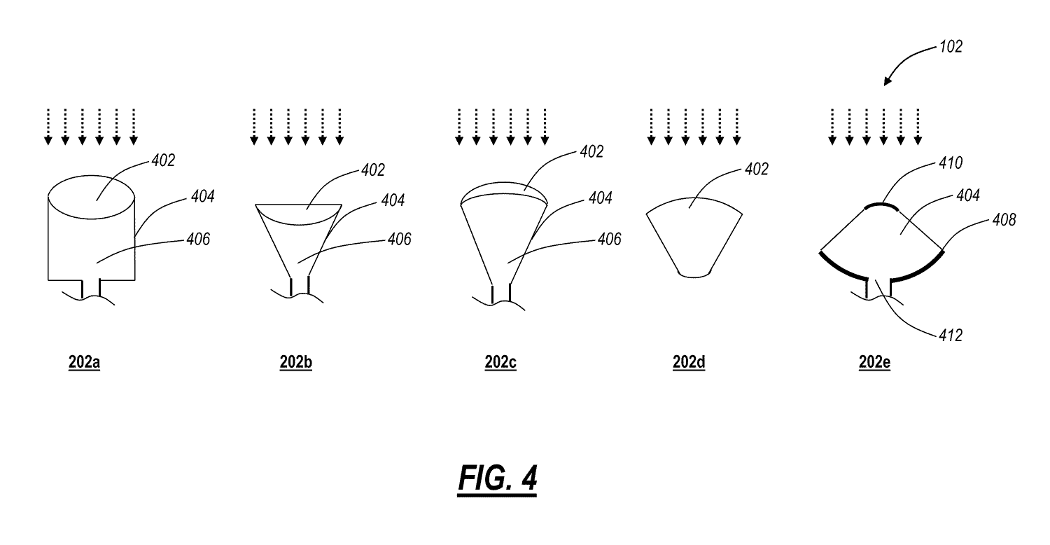

Referring to FIG. 2, multiple solar collectors 200 are illustrated for providing a flatter and compact arrangement, i.e. a low-profile design, according to an exemplary embodiment of the present invention. FIG. 2 illustrates a top view and a side view of the multiple solar collectors 200. In the top view, the multiple solar collectors 200 can be arranged side-by-side along an x- and y-axis. Each of the solar collectors 200 includes a focusing/collimating element 202 which is configured to concentrate solar radiation 102 into a corresponding light guide 204. The focusing/collimating element 202 is illustrated in FIG. 2 with an exemplary profile, and additional exemplary profile shapes are illustrated in FIG. 4.

The focusing/collimating element 202 focuses the solar radiation 102 into a cone of light with a numerical aperture smaller than the numerical aperture of the light guide 204. The focusing/collimating element 202 can be made out of a material transparent to infrared solar radiation, such as FEP. The focusing/collimating element 202 can be a solid material or hollow with a flexible skin that allows the element 202 to be formed by inflating it with a gas. Forming the element though inflation provides weight and material costs advantages.

The light guides 204 can be constructed out of a material that is optically transparent in the infrared region, such as FEP, glass, or other fluorinated polymers in the Teflon® family, or the light guides 204 can be made out of a thin tube (e.g., FEP) filled with a fluid, such as Germanium tetrachloride or Carbon tetrachloride, that is transparent to infrared radiation. Advantageously, the light guides 204 include a material selected so that it has close to zero absorption in the wavelengths of the solar energy 102. The tube material must have a higher index of refraction than the fluid inside it in order to create a step index light guide that allows propagation of the concentrated solar radiation. The array of the multiple solar collectors 200 can extend in the X and Y direction as needed to collect more solar energy.

The focusing/collimating element 202, the light guide 204 and the interface 206 can be rotatably attached to a solar tracking mechanism (not shown). The tracking mechanism is configured to ensure the focusing/collimating element 202 continuously points toward the sun. A microcontroller (not shown) similar to the microcontroller 142 in FIG. 1 can control the tracking mechanism along with other functions of the multiple solar collectors 200. The tracking mechanism can individually point each of the focusing/collimating elements 202 towards the Sun, or alternatively, a group tracking mechanism (not shown) can align a group of elements 202 together.

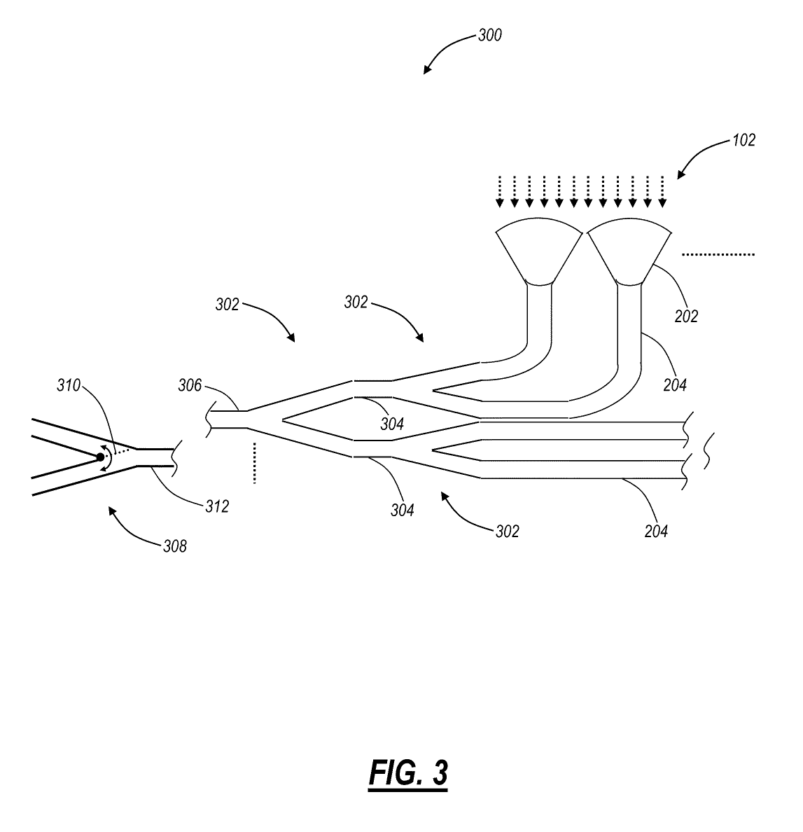

Referring to FIG. 3, a mechanism 300 is illustrated for combining solar radiation 102 from the multiple light guides 204 in FIG. 2 according to an exemplary embodiment of the present invention. The multiple light guides 204 are configured to receive concentrated solar radiation from the focusing/collimating elements 202 and to guide it and release it inside a hot end of multiple engines and/or generators. Optical couplers 302 can be utilized to combine multiple light guides 204 into a single output 304. For example, FIG. 3 illustrates four total light guides 204 combined into a single output 306 through a total of three cascaded optical couplers 302. Those of ordinary skill in the art will recognize that various configurations of optical couplers 302 can be utilized to combine an arbitrary number of light guides 204. The optical couplers 204 which are deployed in a tree configuration in FIG. 3 reduce the number of light 204 guides reaching the engines and/or generators. Alternatively, each light guide 204 could be directed separately into the engines and/or generators.

An optical splitter 308 and an optical switch 310 can also be included in the optical path (illustrated connected to a light guide 312 which includes a combination of all of the light guides 204) at an optimum location along each light guide 204 leading to the engines and/or generators. The optical splitter 308 and optical switch 310 permit pulsation of the concentrated solar energy into one or more piezoelectric generators. Each branch (e.g., two or more branches) of the optical splitter 308 leads to a different engine or generator. The optical switch 310 sequentially directs the concentrated solar energy traveling along the light guide 312 into different arms of the optical splitter 308. For example, the engines and/or generators can include offset heating cycles with the optical splitter 308 and the optical switch 310 directing solar energy 102 into each engine/generator at its corresponding heating cycle. Advantageously, this improves efficiency ensuring that collected solar energy 102 is not wasted (as would occur if there was a single engine because the single engine only requires the energy during the heating cycle).

The optical switch 310 can be integrated into the optical splitter 308 as indicated in FIG. 3 or it can exist independently in which case the optical splitter 308 could be eliminated and the optical switch 310 can have the configuration presented in FIG. 1 (i.e., optical switch 126 and reflecting surfaces 128). In the case where the optical switch 310 is independent of the light guide 312, the light guide termination is designed to collimate the light directed towards the optical switch 310. The selection of the optimum points where the optical splitters 308 are inserted depends on the power handling ability of the optical switch 310 and on economic factors. For example, if the optical switch 310 is inserted in the optical path closer to the engines and/or generators, then fewer switches 310 and shorter light guides 204 are needed, but the optical switches 310 need to be able to handle higher light intensities.

Referring to FIG. 4, various designs are illustrated for the focusing/collimating element 202a-202e according to an exemplary embodiment of the present invention. The focusing/collimating element 202a, 202b, 202c each include an optically transparent solid material 402 shaped in either a bi-convex (element 202a), a plano-convex (element 202b), and a meniscus form (element 202c), all of which have the purpose to focus the incoming solar energy 102. Additionally, each of the elements 202a, 202b, 202c also include a flexible “skin” material 404 that together with the optically transparent solid material 402 form an inflatable structure 406 which can be inflated with air or a different gas. The air/gas pressure in the inflatable structure 406 can be dynamically controlled to maintain an optimum focal distance between the solid material 402 and the engines and/or generators. The optically transparent solid material 402 and the flexible “skin” material 404 are made out of a material transparent to visible and infrared solar radiation, such as FEP, for example. The focusing/collimating element 202d is a solid convex focusing element constructed entirely of the optically transparent solid material 402.

The focusing/collimating element 202e includes an inflatable dual reflector including a primary reflecting surface 408 and a smaller secondary reflecting surface 410 inside an inflatable structure 406. The primary reflecting surface 408 and the secondary reflecting surface 410 are configured to collectively concentrate the solar radiation 102 into an opening 412 that leads to the light guide 204. Both reflecting surfaces 408, 410 can be rigid or flexible such as metalized films or only the secondary reflector 410 can be made out of a rigid material with a high precision reflective surface shape. In this case, the secondary reflector 410 can be directly attached to the transparent material 404 or can be sealed to it (impermeable to air) around the perimeter of the secondary reflector 410. Some of the metals that can be used for metalizing a thin reflector layer on the polymer substrate material of the inflatable collector can include gold, aluminum, silver, or dielectric materials. The preferred surface to be metalized is the inside of the inflatable solar collector such that it is protected from contamination, scratching, weather, or other potentially damaging elements.

Techniques to increase surface reflectivity (such as multi layer dielectric coatings) to almost 100% can be utilized. Again, the air/gas pressure can be dynamically controlled, based on feedback from pressure sensors monitoring the inside pressure of the inflatable focusing element, to maintain the optimum focal distance. All transparent materials through which solar radiation and concentrated solar radiation passes through can have their surfaces covered with broad band anti-reflective coatings in order to maximize light transmission. The designs of the focusing elements 202 presented in FIG. 3 are for illustration purposes and those of ordinary skill in the art will recognize other designs are possible that would meet the purpose and functionality of the focusing elements 202.

The multiple solar collectors 200 can be utilized in buildings, such as office buildings, homes, etc. For example, multiple focusing/collimating elements 202 can be placed on a roof with the light guides 204 extending into the building towards a service area, basement, etc. to the engines and/or generators. Additionally, the light guides 204 heat up very little based upon their material construction. Advantageously, the low profile design of the solar collectors 200 enables roof placement and the light guides enable a separate engine location within a building.

Referring to FIG. 5, a modular solar collector 500 is illustrated according to an exemplary embodiment of the present invention. The modular solar collector 500 is similar to the dual-surface reflector 100 described herein in a multi-functional, modular system configuration. Additionally, the modular solar collector 500 can include an inflatable configuration. The modular solar collector 500 includes a common collector subsystem 502 that can be connected to a number of modules, each with different functionality. Four exemplary modules that can be connected to the inflatable dual reflector collector are described in this disclosure: a) an electricity generation module, b) a drinking water module, c) a heating module, and d) a cutting module. Those of ordinary skill in the art will recognize the present invention contemplates additional modules for integration with the modular solar collector 500. Depending on the desired energy output, the modular solar collector 500 and its different modules can be produced in different sizes. For example, a small and light weight modular solar collector 500 can therefore be made to be portable. Such a system can be used in emergency situations, for camping, by soldiers, etc. Also, a number of innovations made to the previously described collector 100, optimizes the operation of the system.

The modular solar collector 500 can have a similar dual reflector arrangement that was described with respect to the dual-surface reflector 100. Specifically, the modular solar collector 500 includes a large surface primary reflector 104, a small secondary reflector 106 placed at or around the focal point of the primary reflector 104, a central small hole 108 disposed within the primary reflector 104, and a support ring 110 disposed around an intersection of the primary reflector 104 and a transparent surface 112. The modular solar collector 500 can be configured in an inflatable configuration where an interior formed by the primary reflector 104, the secondary reflector 106, the support ring 110, and the transparent surface 112 is inflated. The transparent surface 112 provides support for the secondary reflector 106, and the support ring 110 provides support to enable a desired shape of the solar collector 500. The support ring 110 can also be an inflatable component as well. The inflatable solar collector is attached to a solar pointing and tracking mechanism 116 that also controls the air pressure in the collector 500.

Solar radiation 102 enters through the transparent surface 112 and is reflected to the secondary reflector 106 from the primary reflector 104, note that reflector 106 can be concave or convex in shape. From the secondary reflector 106, the concentrated solar radiation passes through the central small hole 108 in the primary reflector 104 to reach the common collector subsystem 502 where a connector 504 allows the attachment of various modules. The connector 504 forms an air tight seal between a particular attached module and the rest of the system that includes the collector 500. The concentrated solar energy that reaches the common collector subsystem 502 is utilized by the particular module that is attached at that time.

The modular solar collector 500 can be optimized to filter out the solar radiation 102 that is not needed, e.g. through a filtering element 506. The filtering element 2506 can be integrated directly into the components that form the collector 500. For example, utilizing the schematic in FIG. 1, if we want to filter out the solar radiation 102 with wavelengths longer than 1.7 μm, we can place a filter into the front transparent surface 112 of the collector 500. The filter is made by stacking together multiple optically transparent films of appropriate thicknesses and refractive indexes similar to making dielectric filters commonly used in the optical communication industry. Another option to filter out unwanted solar radiation 102 includes keeping the transparent surface 112 of the collector 500 fully optically transparent (as much as permitted by the intrinsic material properties such as of FEP) and making the primary reflector's 104 surface selectively reflective to only part the solar radiation 102 needed by the system. The rest of the solar radiation 102 will pass through the surface of the primary reflector 104. Here, the primary reflector 104 is made by stacking together multiple optically transparent films of appropriate thicknesses and refractive indexes. A third option to eliminate unwanted radiation is to keep the front transparent surface 112 of the collector 500 fully optically transparent (as much as permitted by the intrinsic material properties such as of FEP), use a broad band reflecting surface (such as metalized film) for the primary reflector 104, and make the secondary reflector's 106 surface selectively reflective to only the solar radiation needed by the system. The rest of the solar radiation will pass through the surface of the secondary reflector 106. Here, the secondary reflector 106 can be made by stacking together multiple optically transparent films of appropriate thicknesses and refractive indexes to create a dielectric reflector.

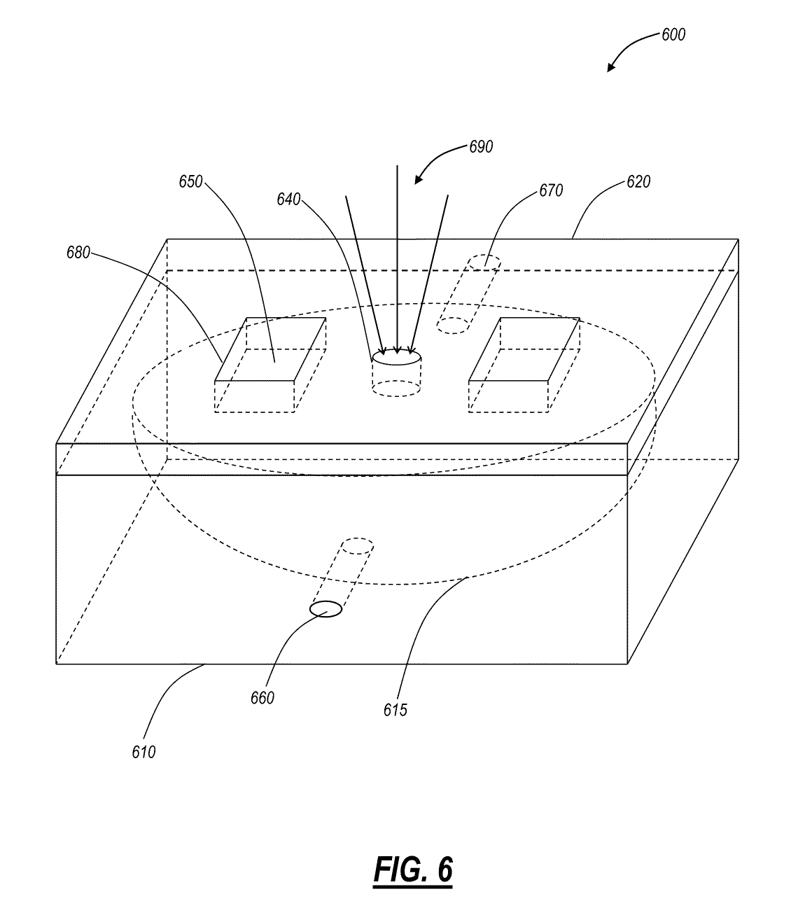

Referring to FIG. 6, a concentrated photovoltaic (CPV) module 600 is illustrated according to an exemplary embodiment of the present invention. The CPV module 600 includes a base block 610 with a cavity 615 formed or defined within the interior of the module 600. The CPV module 600 further includes a top block 620, an optical window 640 disposed in the top block 620, one or more photovoltaic (PV) cells 650 disposed in or attached to the top block 620, and ports 660, 670 extending between the cavity 615 and an exterior of the base block 610. In this exemplary embodiment, the top block 620 is shown disposed to the base block 610 forming the cavity 615. Alternatively, the top block 620 may be integrally formed with the base block 610. The cavity 615 may be formed within the base block 610 and the ports 660, 670 may be drilled or the like through the base block 610. In one exemplary embodiment, the base block 610 may be integrally formed as a block and the cavity 615 and the ports 660, 670 formed from the integrally formed block. In another exemplary embodiment, the base block 610 may be formed with the cavity 615 and the ports 660, 670 included. The cavity 615 may include a surface coated with a material that has high, diffuse reflectance with Lambertian distribution such as sintered polytetrafluoroethylene (PTFE), pressed magnesium oxide powder, pressed barium sulfate powder, or other ceramic materials. Alternatively, the entire base block 610 may be made from a material that has high, diffuse reflectance.

In the exemplary embodiment of FIG. 6, the cavity 615 has a spherical cup shape. The shape of the cavity 615 may be different than a spherical cup, such as, for example, an elliptical shape, a dome shape, a conical shape, an oval shape, a parabolic shape, etc. Of note, the shape of the cavity 615 is a function of the number of PV cells 650 and the spatial arrangement of the PV cells 650. Specifically, the shape of the cavity 650 is configured to optimize a uniform energy distribution from the optical window 640 to the cavity 615 to the various PV cells 650. The top block 620 may include openings 680 adapted to hold the various PV cells 650. In FIG. 6, the top block 620 includes two of the openings 680 for two PV cells 650. Those of ordinary skill in the art will recognize the top block 620 may be configured to hold an arbitrary number of PV cells 650 with the cavity 615 dimensioned and shaped accordingly to provide a uniform energy distribution to each of the arbitrary number of PV cells 650.

The top block 620 has a small hole, centrally formed into it, that is covered by the optical window 640. The CPV module 600 is configured to operate with a solar collector/concentrator, such as, for example, the dual-surface reflector 100, the multiple solar collectors 200, the modular solar collector 500, and the like. Specifically, the solar collector/concentrator is configured to provide concentrated solar radiation 690 to the optical window 640. The optical window 640 may include a material substantially transparent to visible and infrared solar radiation, such as FEP or the like. The solar collector/concentrator is configured to provide concentrated solar energy such as, for example, concentrated solar radiation 690 equivalent to hundreds up to thousands of Suns. The concentrated solar radiation 690 is configured to reflect off of the cavity 615 and be uniformly distributed to the various PV modules 650. As described herein, any number of PV cells 650 may be placed into openings 680 and/or the top block 620 may include any number of openings 680. The cells placement is such that all PV cells are opened to the cavity 215. The number of PV cells 650 may be optimized as a function of the size of the primary collector and the maximum solar intensity tolerated by each of the PV cells 650. With adequate cooling, current PV cells may operate at solar concentrations of thousands of Suns.

The two ports 660, 670 are openings between the cavity 615 and the exterior of the block 610. Typically, the PV cells 650 are cooled by attaching heat removal devices such as common heat exchangers or heat pipes on their back surface. In various exemplary embodiments of the present invention, the PV cells 650 may utilize this typical back surface cooling arrangement including heat exchangers or heat pipes. Additionally, the two ports 660, 670 allow for a cooling fluid to be circulated inside the cavity 615 to also remove heat and cool the front surface of the PV cells 650. The cooling fluid must be substantially optically transparent and non-electrically conductive. For example, the cooling fluid may include Germanium or Carbon tetrachloride. The circulating cooling fluid removes heat from the PV cells 650 and discards it through a heat exchanger for example into the air. Alternatively, a heat pipe arrangement can be employed with the cooling fluid to achieve higher rates of cooling. Thus, one of the ports 660, 670 may be used for fluid intake and the other for fluid exhaust.

In operation, the novel CPV module 600 operates in the following manner: the solar collector gathers, concentrates, and focuses the energy into the cavity 615, the surface of the cavity 615 reflects the focused solar energy into a uniform diffuse Lambertian distribution that illuminates the surface of the PV cells 650 disposed on or in the top block 620, and as a result the PV cells 650 produce electricity. The electricity output from the PV cells 650 may be connected in series or in parallel.

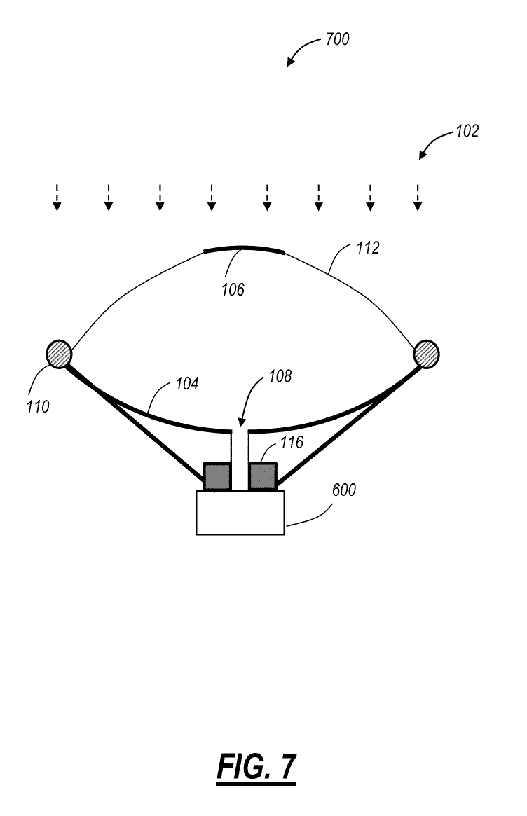

Referring to FIG. 7, a concentrated photovoltaic (CPV) system 700 is illustrated according to an exemplary embodiment of the present invention. The CPV system 700 includes a portion of the dual-surface reflector 100 described in FIG. 1. The dual-surface reflector 100 includes a large surface primary reflector 104 that focuses the solar radiation onto a small secondary reflector 106 placed at or around the focal point of the primary reflector 104, a support ring 110, and a transparent surface 112. Note, the various components of the dual-surface reflector 100 may be inflatable. Also, the CPV system 700 may include a solar pointing and tracking mechanism 116 that also controls the air pressure inside the inflatable components thereby maintaining proper positioning with respect to the Sun. The combination of primary reflector 104 and secondary reflector 106 is designed such as to focus the solar light 102 through the opening 108 and through the window 640 (described in FIG. 1) of the CPV module 600. The CPV module 600 forms an air tight seal with the rest of the system 700.

The dual-surface reflector 100 may be optimized to filter out the solar radiation that is not needed. A filtering element may be integrated directly into the components that form the dual-surface reflector 100. For example, utilizing the schematic in FIG. 7, if it is desired to filter out the solar radiation with wavelengths longer than 1.7 μm, a filter may be placed into the front transparent surface 112 of the dual-surface reflector 100. The filter is made by stacking together multiple optically transparent films of appropriate thicknesses and refractive indexes similar to making dielectric filters commonly used in the optical communication industry. A second possibility to filter out unwanted solar radiation is to keep the front transparent surface 112 of the reflector 100 fully optically transparent (as much as permitted by the intrinsic material properties such as of FEP) and make the primary reflector's surface 104 selectively reflective to only the solar radiation needed by the system 700. The rest of the solar radiation will pass through the surface of the primary reflector 104. The primary reflector 104 is made by stacking together multiple optically transparent films of appropriate thicknesses and refractive indexes. A third method to eliminate unwanted radiation is to keep the front transparent surface 112 of the collector fully optically transparent (as much as permitted by the intrinsic material properties such as of FEP), use a broad band reflecting surface (such as metalized film) for the primary reflector 104, and make the secondary reflector's surface 106 selectively reflective to only the solar radiation needed by the system 700. The rest of the solar radiation will pass through the surface of the secondary reflector 106. One embodiment of the secondary reflector 106 is to make it by stacking together multiple optically transparent films of appropriate thicknesses and refractive indexes to create a dielectric reflector.

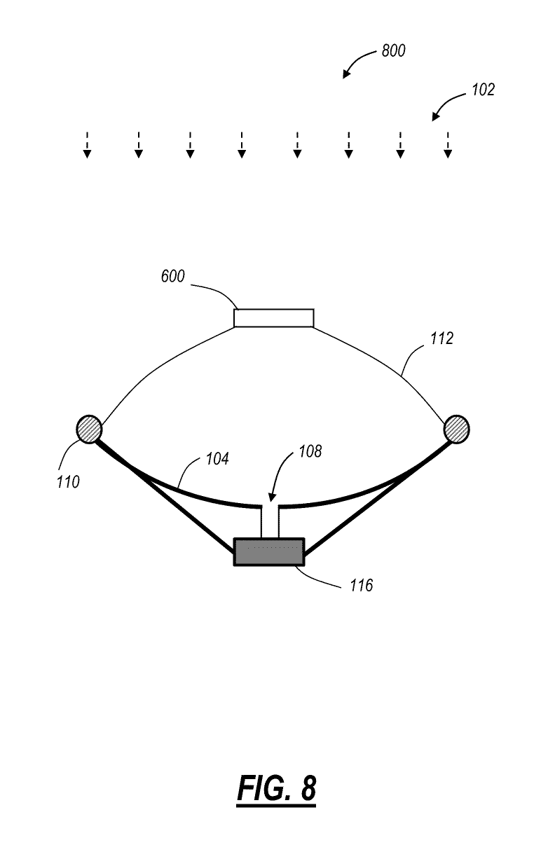

Referring to FIG. 8, a concentrated photovoltaic (CPV) system 800 is illustrated according to an exemplary embodiment of the present invention. The CPV system 800 includes an inflatable solar collector in a configuration in which the CPV module 600 is located approximately at the focal point of the primary reflector 104. The CPV module 600 forms an air sealed connection with the optically transparent front surface 112 of the solar collector. This arrangement eliminates the need for a secondary reflector, and in this case the opening 108 is used mainly for pressure regulation inside the inflatable collector through the base 116.

Although the present invention has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention and are intended to be covered by the following claims.

What is claimed is:

1. A concentrated photovoltaic module, comprising:
a base comprising a cavity disposed therein;
a top portion disposed to the base;
an optical window in the top portion;
one or more photovoltaic cells disposed to the top portion; and
two or more openings in the base configured to provide a cooling fluid within the cavity.

2. The concentrated photovoltaic module of claim 1, wherein the cavity is dimensioned and shaped based upon the number of the one or more photovoltaic cells.

3. The concentrated photovoltaic module of claim 2, wherein the cavity is configured to provide a Lambertian distribution of concentrated solar radiation from the optical window to each of the one or more photovoltaic cells.

4. The concentrated photovoltaic module of claim 1, wherein the cavity is coated with a high, diffuse reflectance material.

5. The concentrated photovoltaic module of claim 4, wherein the high, diffuse reflectance material comprises any of polytetrafluoroethylene, pressed magnesium oxide powder, and pressed barium sulfate powder.

6. The concentrated photovoltaic module of claim 1, wherein the base comprises a high, diffuse reflectance material, and wherein the cavity is formed in the base.

7. The concentrated photovoltaic module of claim 6, wherein the high, diffuse reflectance material comprises any of polytetrafluoroethylene, pressed magnesium oxide powder, and pressed barium sulfate powder.

8. The concentrated photovoltaic module of claim 1, wherein the optical window is configured to receive concentrated solar radiation from a solar collector, and wherein the concentrated solar radiation comprises concentration of at least hundreds of Suns.

9. The concentrated photovoltaic module of claim 1, wherein the cooling fluid is substantially optically transparent and non-electrically conductive.

10. The concentrated photovoltaic module of claim 9, wherein the cooling fluid comprises any of Germanium and Carbon tetrachloride.

11. A concentrated photovoltaic system, comprising:
a concentrated photovoltaic module comprising:
a base comprising a cavity disposed therein;
a top portion disposed to the base;
an optical window in the top portion;
one or more photovoltaic cells disposed to the top portion; and
two or more openings in the base configured to provide a cooling fluid within the cavity; and
a solar collector connected to the optical window.

12. The concentrated photovoltaic system of claim 11, wherein the cavity is dimensioned and shaped based upon the number of the one or more photovoltaic cells, and wherein the cavity is configured to provide a Lambertian distribution of concentrated solar radiation from the optical window to each of the one or more photovoltaic cells.

13. The concentrated photovoltaic system of claim 11, wherein the cavity is coated with a high, diffuse reflectance material, and wherein the high, diffuse reflectance material comprises any of polytetrafluoroethylene, pressed magnesium oxide powder, and pressed barium sulfate powder.

14. The concentrated photovoltaic system of claim 11, wherein the base comprises a high, diffuse reflectance material, and wherein the cavity is formed in the base, and wherein the high, diffuse reflectance material comprises any of polytetrafluoroethylene, pressed magnesium oxide powder, and pressed barium sulfate powder.

15. The concentrated photovoltaic system of claim 11, wherein the cooling fluid is substantially optically transparent and non-electrically conductive, and wherein the cooling fluid comprises any of Germanium and Carbon tetrachloride.

16. The concentrated photovoltaic system of claim 11, wherein the solar collector comprises:
a primary reflector;
a secondary reflector configured to receive solar energy reflected from the primary reflector and concentrate the solar energy; and
an opening in the primary reflector, wherein the concentrated solar energy is provided by the secondary reflector to the opening;
wherein the primary reflector and the secondary reflector each comprise inflatable components, and wherein the concentrated photovoltaic module is disposed to the opening in the primary reflector.

17. The concentrated photovoltaic system of claim 11, wherein the solar collector comprises:
a primary reflector;
a transparent and flexible material disposed to the primary reflector, wherein the transparent and flexible material is substantially optically transparent in the infrared region; and
wherein the primary reflector and the transparent and flexible material each comprise inflatable components, and wherein the concentrated photovoltaic module is disposed to the transparent and flexible material.

18. A concentrated photovoltaic method, comprising:
receiving concentrated solar radiation at an opening;
deflecting the concentrated solar radiation off a cavity to one or more photovoltaic cells, wherein the concentrated solar radiation is deflected in a uniform distribution to each of the one or more photovoltaic cells;
generating electricity at each of the one or more photovoltaic cells based upon the concentrated solar radiation; and
cooling each of the one or more photovoltaic cells utilizing a cooling fluid in contact with at least one of the one or more photovoltaic cells.

19. The concentrated photovoltaic method of claim 18, wherein the cooling fluid is substantially optically transparent and non-electrically conductive.

20. The concentrated photovoltaic method of claim 19, wherein the cooling fluid comprises any of Germanium and Carbon tetrachloride.
